(19) United States
(12) Patent Application Publication
(10) Pub. No.: US 2025/0109057 A1
(43) Pub. Date: Apr. 3, 2025

(54) GLASS COMPOSITION, GLASS FIBER INCLUDING THE SAME, AND ELECTRONIC PRODUCT INCLUDING THE GLASS FIBER

(71) Applicant: FULLTECH FIBER GLASS CORP., Douliu City (TW)

(72) Inventors: Hsien-Chung HSU, Douliu City (TW); Bih-Cherng CHERN, Douliu City (TW); Ching-Shuo CHANG, Douliu City (TW); Chih-Yuan CHANG, Douliu City (TW); Wei-Chih LO, Douliu City (TW); Wen-Ho HSU, Douliu City (TW)

(21) Appl. No.: 18/647,991

(22) Filed: Apr. 26, 2024

(30) Foreign Application Priority Data
Sep. 28, 2023 (TW) 112137397

(51) Int. Cl. C03C 3/118; C03C 3/093; C03C 13/00; H01Q 1/42; H05K 1/03

(52) U.S. Cl. CPC C03C 3/118; C03C 3/093; C03C 13/00; H01Q 1/42; H05K 1/0306; C03C 2213/00

(57) ABSTRACT

A glass composition includes, based on 100 wt % of the glass composition, silicon dioxide present in an amount ranging from 45 wt % to 61 wt %, aluminum oxide present in an amount (A) ranging from 15 wt % to 22 wt %, calcium oxide present in an amount (C) ranging from 0.1 wt % to 6 wt %, magnesium oxide present in an amount (M) of greater than 0 wt % and lower than 2 wt %, zinc oxide present in an amount of greater than 0 wt % and lower than 8 wt %, copper oxide present in an amount of greater than 0 wt % and lower than 7 wt %, and boron oxide present in an amount of greater than 6 wt % and lower than 18 wt %. A glass fiber including the glass composition, and an electronic product including the glass fiber are also provided.

### CROSS-REFERENCE TO RELATED APPLICATION

This application claims priority to Taiwanese Invention patent application No. 112137397, filed on Sep. 28, 2023, which is incorporated by reference herein in its entirety.

### FIELD

The disclosure relates to a glass composition and a glass fiber including the same. The disclosure also relates to an electronic product including the glass fiber.

### BACKGROUND

In response to rapid changes in technology, electronic products are currently manufactured to achieve a high transmission efficiency and to combat the adverse effects arising from residual stress caused by thermal expansion during operation thereof. Therefore, a glass fiber cloth used as a reinforcing material in a printed circuit board is not only required to have low dielectric properties (i.e., low dielectric constant and low dielectric loss tangent) so as to satisfy the demand for such high transmission efficiency, but also to have low coefficient of thermal expansion so that the electronic products made therefrom can be less susceptible to deformation due to temperature changes.

Specifically, the glass fiber cloth is woven from a glass fiber yarn. The glass fiber yarn is made of a glass fiber, and the glass fiber is fabricated by melting and spinning a glass composition. If a crystallization phenomenon occurs in the glass composition during the process of the glass composition being fabricated into the glass fiber, the spinning operation of the glass composition would not proceed smoothly, which not only makes the quality of the glass fiber thus produced poor, but also has a negative impact on the properties of the glass fiber.

### SUMMARY

Accordingly, in a first aspect, the present disclosure provides a glass composition, which can alleviate at least one of the drawbacks of the prior art. The glass composition includes, based on 100 wt % of the glass composition:
silicon dioxide present in an amount ranging from 45 wt % to 61 wt %;
aluminum oxide present in an amount (A) ranging from 15 wt % to 22 wt %;
calcium oxide present in an amount (C) ranging from 0.1 wt % to 6 wt %;
magnesium oxide present in an amount of (M) greater than 0 wt % and lower than 2 wt %;
zinc oxide present in an amount of greater than 0 wt % and lower than 8 wt %;
copper oxide present in an amount of greater than 0 wt % and lower than 7 wt %; and
boron oxide present in an amount (B) of greater than 6 wt % and lower than 18 wt %,
wherein the amount (C) of the calcium oxide, the amount (M) of the magnesium oxide, the amount (A) of the aluminum oxide, and the amount (B) of the boron oxide satisfy the following Equation (I):

$$x = \frac{C + M}{A} + \frac{C + M}{B} , \qquad ( I )$$

where x ranges from 0.3 to 1.5.

In a second aspect, the present disclosure provides a glass fiber, which can alleviate at least one of the drawbacks of the prior art. The glass fiber includes the aforesaid glass composition.

In a third aspect, the present disclosure provides an electronic product, which can alleviate at least one of the drawbacks of the prior art. The electronic product includes the aforesaid glass fiber.

### DETAILED DESCRIPTION

It is to be understood that, if any prior art publication is referred to herein, such reference does not constitute an admission that the publication forms a part of the common general knowledge in the art, in Taiwan or any other country.

For the purpose of this specification, it will be clearly understood that the word “comprising” means “including but not limited to”, and that the word “comprises” has a corresponding meaning.

Unless otherwise defined, all technical and scientific terms used herein have the meaning commonly understood by a person skilled in the art to which the present disclosure belongs. One skilled in the art will recognize many methods and materials similar or equivalent to those described herein, which could be used in the practice of the present disclosure. Indeed, the present disclosure is in no way limited to the methods and materials described.

### [Glass Composition]

The present disclosure provides a glass composition. According to the present disclosure, the glass composition includes silicon dioxide (SiO₂), aluminum oxide (Al₂O₃), calcium oxide (CaO), magnesium oxide (MgO), zinc oxide (ZnO), copper oxide (CuO), and boron oxide (B₂O₃).

According to the present disclosure, based on 100 wt % of the glass composition, the silicon dioxide is present in an amount ranging from 45 wt % to 61 wt %, the aluminum oxide is present in an amount (A) ranging from 15 wt % to 22 wt %, the calcium oxide is present in an amount (C) ranging from 0.1 wt % to 6 wt %, the magnesium oxide is present in an amount (M) of greater than 0 wt % and lower than 2 wt %, the zinc oxide is present in an amount of greater than 0 wt % and lower than 8 wt %, the copper oxide is present in an amount of greater than 0 wt % and lower than 7 wt %, and the boron oxide is present in an amount (B) of greater than 6 wt % and lower than 18 wt %.

According to the present disclosure, the amount (C) of the calcium oxide, the amount (M) of the magnesium oxide, the amount (A) of the aluminum oxide, and the amount (B) of the boron oxide satisfy the following Equation (I):

$$x = \frac{C + M}{A} + \frac{C + M}{B} , \qquad ( I )$$

where x ranges from 0.3 to 1.5.

In particular, when the amount (C) of the calcium oxide, the amount (M) of the magnesium oxide, the amount (A) of the aluminum oxide, and the amount (B) of the boron oxide in the glass composition satisfy the Equation (I) under the condition where the amount of each of the abovementioned components (i.e., the silicon dioxide, the aluminum oxide, the calcium oxide, the magnesium oxide, the zinc oxide, the copper oxide, and the boron oxide) fell within its range as described above (especially the amount (M) of the magnesium oxide should be greater than 0 wt % and lower than 2 wt %), the glass composition can be made to have a low coefficient of thermal expansion, a low dielectric constant, a low dielectric loss tangent, and a good spinning processability.

The role of each of the aforementioned components and the amount thereof in the glass composition of the present disclosure are further described in detail below.

The silicon dioxide is a major component of the glass composition, and when the amount of the silicon dioxide ranges from 45 wt % to 61 wt % based on 100 wt % of the glass composition, the viscosity of the glass composition can be reduced, thereby facilitating the melting of the glass composition.

When the amount of the aluminum oxide ranges from 15 wt % to 22 wt % based on 100 wt % of the glass composition, not only can the viscosity of the glass composition be reduced, which facilitates the melting of the glass composition, but also the glass composition becomes less likely to crystalize during the process of the glass composition being manufactured into a glass fiber, thereby improving spinning processability of the glass composition.

When the amount of the calcium oxide ranges from 0.1 wt % to 6 wt % based on 100 wt % of the glass composition, not only can the viscosity of the glass composition be reduced, which facilitates the melting of the glass composition, but also the glass composition becomes less likely to crystalize during the process of the glass composition being manufactured into the glass fiber, thereby improving the spinning processability of the glass composition, and reducing coefficient of thermal expansion of the glass composition.

When the amount of the magnesium oxide is greater than 0 wt % and lower than 2 wt % based on 100 wt % of the glass composition, not only can the viscosity of the glass composition be reduced, which facilitates the melting of the glass composition, but also the structure of the glass composition can be made to be more compact, so that both the glass composition and the glass fiber made from the glass composition have advantages of low coefficient of thermal expansion and low dielectric constant.

When the amount of the zinc oxide is greater than 0 wt % and lower than 8 wt % based on 100 wt % of the glass composition, coefficient of thermal expansion of both the glass composition and the glass fiber made from the glass composition can be reduced.

When the amount of the copper oxide is greater than 0 wt % and lower than 7 wt % based on 100 wt % of the glass composition, not only is the structure of the glass composition made to be more compact, thereby reducing coefficient of thermal expansion of both the glass composition and the glass fiber made from the glass composition, but also the glass composition becomes less likely to crystalize during the process of the glass composition being manufactured into the glass fiber, thereby improving the spinning processability of the glass composition.

When the amount of the boron oxide is greater than 6 wt % and lower than 18 wt % based on 100 wt % of the glass composition, not only can the viscosity of the glass composition be reduced, which facilitates the melting of the glass composition, but also the glass composition becomes less likely to crystalize during the process of the glass composition being manufactured into the glass fiber, thereby improving the spinning processability of the glass composition. In addition, by virtue of such amount of the boron oxide, the structure of the glass composition can be made more compact, so that both the glass composition and the glass fiber made from the glass composition have advantages of low coefficient of thermal expansion, low dielectric constant, and low dielectric loss tangent.

In certain embodiments, the glass composition may further include fluorine (F₂), and the fluorine may be present in an amount (F) of greater than 0 wt % and not greater than 1 wt % based on 100 wt % of the glass composition. When the glass composition further includes the fluorine, the amount (C) of the calcium oxide, the amount (M) of the magnesium oxide, the amount (A) of the aluminum oxide, and the amount (B) of the boron oxide still satisfy the aforesaid Equation (I). Additionally, the amount (C) of the calcium oxide, the amount (M) of the magnesium oxide, the amount (A) of the aluminum oxide, the amount (B) of the boron oxide, and the amount (F) of the fluorine satisfy the following Equation (II):

$$y = \frac{C + M}{A} + \frac{C + M}{B + F} , \qquad ( II )$$

where y ranges from 0.3 to 1.5.

When the amount of the fluorine is greater than 0 wt % and not greater than 1 wt % based on 100 wt % of the glass composition, not only can the viscosity of the glass composition be reduced, which facilitates the melting of the glass composition, but also the glass composition can be conferred with a lower dielectric constant as well as a lower dielectric loss tangent.

In some embodiments, the glass composition may further include an impurity which may be derived from and contained in any of the aforesaid components used for making the glass composition. In still some embodiments, the impurity may be present in an amount of not greater than 1.2 wt % based on 100 wt % of the glass composition. In yet some embodiments, the impurity may be selected from the group consisting of sodium oxide (Na₂O), potassium oxide (K₂O), iron oxide (Fe₂O₃), titanium dioxide (TiO₂), and combinations thereof.

In certain embodiments, the glass composition may have a coefficient of thermal expansion of not greater than 2.8 ppm/° C., a dielectric constant of not greater than 4.9 and a dielectric loss tangent of not greater than 0.0035 at a frequency of 10 GHz, and a temperature of forming window of greater than 100° C. Such temperature of forming window, i.e., greater than 100° C., is beneficial to the spinning process when the glass composition is manufactured into the glass fiber.

### [Glass Fiber]

The present disclosure also provides a glass fiber that includes the aforesaid glass composition.

An example of a method for manufacturing the glass fiber may include subjecting the glass composition to a melting treatment so as to obtain a liquid glass, followed by spinning the liquid glass to obtain the glass fiber. However, the method for manufacturing the glass fiber is not limited to the foregoing example. It should be noted that the operation conditions and specific procedures for manufacturing the glass fiber are within the expertise and routine skills of those skilled in the art. Moreover, because the amount of each of the components in the glass composition may be different in different situations, the operation conditions with respect to the method for manufacturing the glass fiber may be slightly different and may be adjusted using technology well known to those skilled in the art.

Because the glass composition of the present disclosure has advantages of low coefficient of thermal expansion, low dielectric constant, low dielectric loss tangent, and good spinning processability, the glass fiber made from the glass composition also has characteristics of low coefficient of thermal expansion, low dielectric constant, and low dielectric loss tangent. In some embodiments, the glass fiber may have a coefficient of thermal expansion of not greater than 2.8 ppm/° C., and a dielectric constant of not greater than 4.9 and a dielectric loss tangent of not greater than 0.0035 at a frequency of 10 GHz.

### [Electronic Product]

The present disclosure further provides an electronic product that includes the aforementioned glass fiber. Because the glass fiber has characteristics of low coefficient of thermal expansion, low dielectric constant, and low dielectric loss tangent, the electronic product including the glass fiber has a good transmission efficiency and is less susceptible to deformation due to temperature changes.

The types of the electronic product are not limited, as long as the electronic product is manufactured by using the aforesaid glass fiber as an essential material. In certain embodiments, the electronic product may be one selected from the group consisting of a printed circuit board, an integrated circuit carrier board, and a radome.

The present disclosure will be further described by way of the following examples. However, it should be understood that the following examples are intended solely for the purpose of illustration and should not be construed as limiting the present disclosure in practice.

### Preparation of Glass Composition

### Example 1 (E1)

The glass composition of E1 was prepared using the recipe shown in Table 1 and the process described as follow. Briefly, silicon dioxide, aluminum oxide, calcium oxide, magnesium oxide, zinc oxide, copper oxide, boron oxide, and fluorine were mixed, so as to obtain a glass composition. Based on 100 wt % of the glass composition, the silicon dioxide was present in an amount of 55.4 wt %, the aluminum oxide was present in an amount (A) of 18.0 wt %, the calcium oxide was present in an amount (C) of 2.3 wt %, the magnesium oxide was present in an amount (M) of 1.9 wt %, the zinc oxide was present in an amount of 7.0 wt %, the copper oxide was present in an amount of 0.2 wt %, the boron oxide was present in an amount (B) of 14.0 wt %, the fluorine was present in an amount (F) of 0.7 wt %, and impurities including sodium oxide, potassium oxide, and iron oxide, which were derived from the aforesaid components, were present in an amount of 0.5 wt %. The components mentioned above satisfy both the following Equations (I) and (II), where x=0.53, and y=0.52:

$$x = \frac{C + M}{A} + \frac{C + M}{B} ; and \qquad ( I )$$

$$y = \frac{C + M}{A} + \frac{C + M}{B + F} . \qquad ( II )$$

### Examples 2 to 7 (E2 to E7) and Comparative Examples 1 to 3 (CE1 to CE3)

The procedures for preparing the glass composition of each of the Examples 2 to 7 and Comparative Examples 1 to 3 were generally similar to those of Example 1, except that the amount of each component therein was varied as shown in Tables 1 and 2 below. Moreover, the impurities in the glass composition of each of Examples 2 to 7 included sodium oxide, potassium oxide, and iron oxide, and the impurities in the glass composition of each of Comparative Examples 1 to 3 included sodium oxide, potassium oxide, iron oxide, and titanium dioxide.

### Property Evaluation

### A. Preparation of Glass Block

The glass composition of each of Examples 1 to 7 and Comparative Examples 1 to 3 was placed in a high-temperature furnace and heated at a temperature ranging from 1500° C. to 1600° C. for 1 hour to 4 hours, so that the glass composition is in a completely molten state (i.e., a liquid glass). Afterward, the liquid glass was poured into a graphite crucible having a diameter of 40 mm, followed by placing the graphite crucible with the liquid glass therein into an annealing furnace that had been preheated to 800° C., so as to cool down the graphite crucible with the liquid glass therein to room temperature (25° C.), thereby obtaining a glass block of each of Examples 1 to 7 and Comparative Examples 1 to 3.

### B. Determination of Coefficient of Thermal Expansion (CTE)

The glass block of each of Examples 1 to 7 and Comparative Examples 1 to 3 obtained in Section A was cut and ground, so as to obtain a test sample of the glass block having a size of 0.5 cm×0.5 cm×2 cm. Thereafter, the test sample was heated at a heating rate of 10° C./min using a thermomechanical analyzer (Hitachi; model: TMA71000), so that the test sample had length changes respectively at 50° C. and 200° C., thereby enabling calculation of a coefficient of thermal expansion of the glass composition of each of Examples 1 to 7 and Comparative Examples 1 to 3. The results are shown in Tables 1 and 2 below.

### C. Determination of Dielectric Constant (Dk) and Dielectric Loss Tangent (Df)

The glass block of each of Examples 1 to 7 and Comparative Examples 1 to 3 obtained in Section A was polished and ground, so as to obtain a test piece of the glass block having a thickness ranging from 0.60 mm to 0.79 mm. Subsequently, the test piece was subjected to measurements of dielectric constant and dielectric loss tangent at a frequency of 10 GHz using a vector network analyzer (R&S; Model: ZNB20) coupled with a split post dielectric resonator (Waveray Technology Co., Ltd.), thereby obtaining a dielectric constant and a dielectric loss tangent of the glass composition of each of Examples 1 to 7 and Comparative Examples 1 to 3. The results are shown in Tables 1 and 2 below.

### D. Determination of Temperature of Forming Window (ΔT)

First, 2.25 g of the glass block of each of Examples 1 to 7 and Comparative Examples 1 to 3 obtained in Section A was taken and placed in a high-temperature furnace, and then the high-temperature furnace was heated to a certain temperature and maintained at that temperature for 2 hours. After that, the glass block was taken out from the high-temperature furnace and left to cool down to room temperature (25° C.), followed by observation of whether a crystallization phenomenon occurred therein. If crystallization was present in the glass block, the certain temperature was the devitrification temperature of the glass composition. The temperature of forming window (ΔT) of the glass composition was determined by subtracting the devitrification temperature from the temperature at which the glass composition has a viscosity of 1000 poise. The results are shown in Tables 1 and 2 below.

TABLE 1

| | | | E1 | E2 | E3 | E4 | E5 | E6 | E7 |
|---|---|---|---|---|---|---|---|---|---|
| Glass | Components | SiO₂ | 55.4 | 55.3 | 55.8 | 55.3 | 55.3 | 55.7 | 55.5 |
| Composition | (wt %) | Al₂O₃ | 18.0 | 18.0 | 18.3 | 18.2 | 17.2 | 17.8 | 17.2 |
| | | CaO | 2.3 | 2.3 | 2.3 | 2.3 | 2.3 | 1.9 | 2.9 |
| | | MgO | 1.9 | 1.9 | 1.9 | 1.9 | 1.9 | 1.9 | 0.9 |
| | | ZnO | 7.0 | 7.0 | 6.3 | 7.1 | 7.1 | 7.0 | 7.1 |
| | | CuO | 0.2 | 0.3 | 0.2 | 0.2 | 0.2 | 0.2 | 0.2 |
| | | B₂O₃ | 14.0 | 14.0 | 14.0 | 14.0 | 15.0 | 15.0 | 15.2 |
| | | F₂ | 0.7 | 0.7 | 0.7 | 0.5 | 0.5 | 0 | 0.5 |

| | | | | | | | |
|---|---|---|---|---|---|---|---|
| Impurities | 0.5 | 0.5 | 0.5 | 0.5 | 0.5 | 0.5 | 0.5 |
| (wt %) | | | | | | | |
| Total amount | 100 | 100 | 100 | 100 | 100 | 100 | 100 |
| (wt %) | | | | | | | |

| | | | | | | | |
|---|---|---|---|---|---|---|---|
| x value calculated | 0.53 | 0.53 | 0.53 | 0.53 | 0.52 | 0.47 | 0.47 |
| by Equation (I) | | | | | | | |
| y value calculated | 0.52 | 0.52 | 0.52 | 0.52 | 0.52 | 0.47 | 0.46 |
| by Equation (II) | | | | | | | |
| CTE (ppm/° C.) | 2.74 | 2.74 | 2.78 | 2.68 | 2.79 | 2.70 | 2.77 |
| Dk (10 GHz) | 4.83 | 4.87 | 4.86 | 4.89 | 4.83 | 4.89 | 4.86 |
| Df (10 GHz) | 0.0030 | 0.0030 | 0.0029 | 0.0032 | 0.0029 | 0.0034 | 0.0033 |
| ΔT (° C.) | >100 | >100 | >100 | >100 | >100 | >100 | >100 |

TABLE 2

| | | | CE1 | CE2 | CE3 |
|---|---|---|---|---|---|
| Glass | Components | SiO₂ | 57.0 | 59.3 | 55.4 |
| Composition | (wt %) | Al₂O₃ | 19.4 | 18.5 | 18.2 |
| | | CaO | 0.4 | 5.5 | 2.0 |
| | | MgO | 1.9 | 1.9 | 2.2 |
| | | ZnO | 2.0 | 1.0 | 7.0 |
| | | CuO | 0.5 | 6.5 | 0.2 |
| | | B₂O₃ | 17.8 | 6.3 | 14.0 |
| | | F₂ | 0 | 0 | 0 |

| | | | |
|---|---|---|---|
| Impurities | 1.0 | 1.0 | 1.0 |
| (wt %) | | | |
| Total amount | 100 | 100 | 100 |
| (wt %) | | | |

| | | | |
|---|---|---|---|
| x value calculated | 0.25 | 1.57 | 0.53 |
| by Equation (I) | | | |
| y value calculated | 0.25 | 1.57 | 0.53 |
| by Equation (II) | | | |
| CTE (ppm/° C.) | 2.66 | 2.54 | 2.64 |
| Dk (10 GHz) | 4.66 | 5.30 | 4.96 |
| Df (10 GHz) | 0.0032 | 0.0069 | 0.0040 |
| ΔT (° C.) | <50 | — | — |

“—” indicates no measurement was performed because the dielectric constant and the dielectric loss tangent of the glass composition of each of CE2 and CE3 at the frequency of 10 GHz were high, so measurement of temperature of forming window was not conducted subsequently.

Referring to Tables 1 and 2, the glass composition of Comparative Example 1 had an x value of lower than 0.3, and hence had a temperature of forming window of lower than 50° C., and thus the glass composition of Comparative Example 1 is not conducive to the spinning operation when such glass composition was manufactured into a glass fiber. In addition, the glass composition of Comparative Example 2 had an x value of greater than 1.5, and hence had a high in dielectric constant and a high dielectric loss tangent at the frequency of 10 GHz. In contrast, the glass composition of each of Examples 1 to 7, due to components thereof satisfying the aforesaid Equation (I) under the condition where x value ranges from 0.3 to 1.5, had a better coefficient of thermal expansion, a better dielectric constant and dielectric loss tangent at the frequency of 10 GHZ, and a better-temperature of forming window.

Moreover, the glass composition of Comparative Example 3 had a high dielectric constant and a high dielectric loss tangent at the frequency of 10 GHz due to the amount of the magnesium oxide therein being not lower than 2 wt %. In contrast, the glass composition of each of Examples 1 to 7 had a better coefficient of thermal expansion, a better dielectric constant and dielectric loss tangent at the frequency of 10 GHZ, and a better temperature of forming window due to the amount of the magnesium oxide therein being greater than 0 wt % and lower than 2 wt %.

Summarizing the above test results, by virtue of the glass composition of each of Examples 1 to 7 having the silicon dioxide present in the amount ranging from 45 wt % to 61 wt %, the aluminum oxide present in the amount (A) ranging from 15 wt % to 22 wt %, the calcium oxide present in the amount (C) ranging from 0.1 wt % to 6 wt %, the magnesium oxide present in the amount (M) of greater than 0 wt % and lower than 2 wt %, the zinc oxide present in the amount of greater than 0 wt % and lower than 8 wt %, the copper oxide present in the amount of greater than 0 wt % and lower than 7 wt %, and the boron oxide present in the amount (B) of greater than 6 wt % and lower than 18 wt %, based on 100 wt % of the glass composition, and controlling the amount (C) of the calcium oxide, the amount (M) of the magnesium oxide, the amount (A) of the aluminum oxide, and the amount (B) of the boron oxide to satisfy the Equation (I) (i.e., the x value thus obtained ranges from 0.3 to 1.5), the glass composition of each of Examples 1 to 7 has a coefficient of thermal expansion of not greater than 2.8 ppm/° C., a dielectric constant of not greater than 4.9 and a dielectric loss tangent of not greater than 0.0035 at a frequency of 10 GHz, and a temperature of forming window of greater than 100° C.

The glass composition according to the present disclosure has low coefficient of thermal expansion, low dielectric constant, low dielectric loss tangent, and a good spinning processability. Furthermore, because the glass composition according to the present disclosure has good spinning processability, the glass fiber made from the glass composition also has low coefficient of thermal expansion, low dielectric constant, and low dielectric loss tangent, and hence the electronic product including the glass fiber has advantages of having good transmission efficiency and being not susceptible to deformation due to temperature changes.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A glass composition comprising, based on 100 wt % of the glass composition:
silicon dioxide present in an amount ranging from 45 wt % to 61 wt %;
aluminum oxide present in an amount (A) ranging from 15 wt % to 22 wt %;
calcium oxide present in an amount (C) ranging from 0.1 wt % to 6 wt %;
magnesium oxide present in an amount (M) of greater than 0 wt % and lower than 2 wt %;
zinc oxide present in an amount of greater than 0 wt % and lower than 8 wt %;
copper oxide present in an amount of greater than 0 wt % and lower than 7 wt %; and
boron oxide present in an amount (B) of greater than 6 wt % and lower than 18 wt %,
wherein the amount (C) of the calcium oxide, the amount (M) of the magnesium oxide, the amount (A) of the aluminum oxide, and the amount (B) of the boron oxide satisfy the following Equation (I):
$$x = \frac{C + M}{A} + \frac{C + M}{B} , \qquad ( I )$$
where x ranges from 0.3 to 1.5.

2. The glass composition as claimed in claim 1, further comprising fluorine, the fluorine being present in an amount (F) of greater than 0 wt % and not greater than 1 wt % based on 100 wt % of the glass composition.

3. The glass composition as claimed in claim 2, wherein the amount (C) of the calcium oxide, the amount (M) of the magnesium oxide, the amount (A) of the aluminum oxide, the amount (B) of the boron oxide, and the amount (F) of the fluorine satisfy the following Equation (II):
$$y = \frac{C + M}{A} + \frac{C + M}{B + F} , \qquad ( II )$$
where y ranges from 0.3 to 1.5.

4. A glass fiber, comprising a glass composition as claimed in claim 1.

5. An electronic product, comprising a glass fiber as claimed in claim 4.

6. The electronic product as claimed in claim 5, which is a printed circuit board.

7. The electronic product as claimed in claim 5, which is an integrated circuit carrier board.

8. The electronic product as claimed in claim 5, which is a radome.

9. A glass fiber, comprising a glass composition as claimed in claim 2.

10. A glass fiber, comprising a glass composition as claimed in claim 3.
